(19) United States
(12) Patent Application Publication
(10) Pub. No.: US 2026/0282213 A1
(43) Pub. Date: Sep. 17, 2026

(54) GLASS-BASED SUBSTRATES INCLUDING COMPRESSIVE LAYERS, MICROELECTRONIC ARTICLES INCLUDING SAME, AND METHODS OF MAKING SAME

(71) Applicant: CORNING INCORPORATED, CORNING, NY (US)

(72) Inventors: Jason Roy Grenier, Horseheads, NY (US); Chukwudi Azubuike Okoro, Painted Post, NY (US); Garrett Andrew Piech, Corning, NY (US); Robert Anthony Schaut, Horseheads, NY (US)

(21) Appl. No.: 19/552,358

(22) Filed: Feb. 27, 2026

Related U.S. Application Data
(60) Provisional application No. 63/770,429, filed on Mar. 12, 2025.

(51) Int. Cl. H05K 1/02; H05K 1/11; H05K 3/00; H05K 3/22; H05K 1/03

(52) U.S. Cl. CPC H05K 1/0271; H05K 1/115; H05K 3/0026; H05K 3/0047; H05K 3/0052; H05K 3/22; H05K 1/0306; H05K 2203/092; H05K 2203/107; H05K 2203/1194

(57) ABSTRACT

A glass-based substrate includes a first surface and a second surface opposite the first surface, at least one through glass via extending from the first surface to the second surface of the glass-based substrate, and nanoperforations extending from the first surface to the second surface of the glass-based substrate and defining a contour circumscribing the at least one through glass via. The glass-based substrate includes a compressive layer at the first surface of the glass-based substrate, the second surface of the glass-based substrate, a sidewall of the at least one through glass via, and a sidewall of the nanoperforations.

### CROSS-REFERENCE TO RELATED APPLICATIONS

This Application claims the benefit of priority to U.S. Provisional Patent Application Serial Number 63/770429 filed on Mar. 12, 2025, the content of which is relied upon and incorporated herein by reference in its entirety.

### FIELD

The present specification generally relates to glass-based articles and, in particular, to glass-based substrates, microelectronic articles, and methods of making microelectronic articles including a strengthened glass-based substrate that minimizes the likelihood of fractures in the glass-based substrate.

### Technical Background

Glass-based substrates are widely used in microelectronic articles due to attributes such as low dielectric constant, high rigidity, and panel size capability. The glass-based substrates used in microelectronics may include through glass vias (TGVs), which are holes that extend into or through the glass-based substrate and, when conductive materials are deposited inside the holes, can be used to conduct electrical signals. The glass-based substrate may include redistribution layers (RDLs), which are overlays of multiple layers of metal and dielectric materials. Due to the brittle nature of glass, glass fracturing and warpage may occur in glass-based substrates having TGVs and/or RDLs as increased stresses are applied by these layers to the glass-based substrate.

Accordingly, a need exists for glass-based substrates that have improved mechanical performance.

### SUMMARY

According to a first aspect A1, a glass-based substrate comprises: a first surface and a second surface opposite the first surface; at least one through glass via extending from the first surface to the second surface of the glass-based substrate; and nanoperforations extending from the first surface to the second surface of the glass-based substrate and defining a contour circumscribing the at least one through glass via, wherein the glass-based substrate comprises a compressive layer at the first surface of the glass-based substrate, the second surface of the glass-based substrate, a sidewall of the at least one through glass via, and a sidewall of the nanoperforations.

A second aspect A2 includes the glass-based substrate of the first aspect A1, wherein the contour defines a perimeter of at least one die.

A third aspect A3 includes the glass-based substrate of the second aspect A2, wherein the perimeter of the at least one die comprises a rectangle with rounded corners, each of the corners comprising a radius of curvature greater than or equal to 25 µm.

A fourth aspect A4 includes the glass-based substrate of any one of the previous aspects A1-A3, wherein each of the nanoperforations comprises a diameter greater than or equal to 0.5 µm and less than or equal to 5 µm.

A fifth aspect A5 includes the glass-based substrate of any one of the previous aspects A1-A4, wherein an interval between adjacent nanoperforations is greater than or equal to 3 µm and less than or equal to 50 µm.

A sixth aspect A6 includes the glass-based substrate of any one of the previous aspects A1-A5, wherein the glass-based substrate comprises a surface compressive stress greater than or equal to 600 MPa.

A seventh aspect A7 includes the glass-based substrate of any one of the previous aspects A1-A6, wherein the compressive layer at the sidewall of the nanoperforations comprises a depth of layer greater than or equal to 2 µm.

An eighth aspect A8 includes the glass-based substrate of any one of the previous aspects A1-A7, wherein the at least one through glass via comprises a diameter greater than or equal to 5 µm and less than or equal to 200 µm.

A ninth aspect A9 includes the glass-based substrate of any one of the previous aspects A1-A8, wherein the at least one through glass via comprises a metal material disposed therein.

A tenth aspect A10 includes the glass-based substrate of the ninth aspect A9, wherein the metal material comprises copper, aluminum, silver, tin, aluminum-copper, gold, titanium, titanium-tungsten, tantalum, tantalum-nitrogen, chromium, nickel, or combinations thereof.

An eleventh aspect A11 includes the glass-based substrate of any one of the previous aspects A1-A10, wherein the glass-based substrate is strengthened by an ion exchange process, a steam treatment, or a thermal treatment to form the compressive layer.

A twelfth aspect A12 includes the glass-based substrate of any one of the previous aspects A1-A11, wherein a masking material is disposed at least one of on or in the nanoperforations.

A thirteenth aspect A13 includes the glass-based substrate of the twelfth aspect A12, wherein the masking material comprises a polymer or tape.

A fourteenth aspect A14 includes the glass-based substrate of any one of the previous aspects A1-A13, wherein the glass-based substrate comprises a thickness greater than or equal to 0.1 millimeters and less than or equal to 3 millimeters.

A fifteenth aspect A15 includes the glass-based substrate of any of the previous aspects A1-A14, further comprising at least one metal layer and at least one polymer layer disposed on the first surface of the glass-based substrate, the second surface of the glass-based substrate, or both.

According to a sixteenth aspect A16, a microelectronic article comprises: a glass-based substrate comprising a first surface and a second surface opposite the first surface; a metallized through glass via extending from the first surface to the second surface of the glass-based substrate; at least one redistribution layer disposed on the first surface, the second surface, or both, wherein: the glass-based substrate comprises a compressive layer at the first surface of the glass-based substrate, the second surface of the glass-based substrate, an edge of the glass-based substrate, and a sidewall of the at least one through glass via.

A seventeenth aspect A17 includes the microelectronic article of the sixteenth aspect A16, wherein the glass-based substrate comprises an edge strength greater than or equal to 200 MPa, as measured according to a four-point bend test.

An eighteenth aspect A18 includes the microelectronic article of the sixteenth aspect A16, wherein the glass-based substrate comprises a die.

A nineteenth aspect A19 includes the microelectronic article of the eighteenth aspect A18, wherein the die comprises a rectangle with rounded corners, each of the corners comprising a radius of curvature greater than or equal to 25 µm.

A twentieth aspect A20 includes the microelectronic article of any one of the sixteenth through nineteenth aspects A16-A19, wherein the edge of the glass-based substrate comprises vertical striations and a distance between each of the vertical striations is greater than or equal to 3 µm and less than or equal to 50 µm.

A twenty-first aspect A21 includes the microelectronic article of any one of the sixteenth through twentieth aspects A16-A20, wherein the glass-based substrate comprises a surface compressive stress greater than or equal to 600 MPa.

A twenty-second aspect A22 includes the microelectronic article of any one of the sixteenth through twenty-first aspects A16-A21, wherein the compressive layer at the edge of the glass-based substrate comprises a depth of layer greater than or equal to 2 µm.

A twenty-third aspect A23 includes the microelectronic article of any one of the sixteenth through twenty-second aspects A16-A22, wherein the at least one redistribution layer comprises a metal material and a dielectric material.

A twenty-fourth aspect A24 includes the microelectronic article of the twenty-third aspect A23, wherein the metal material comprises copper, aluminum, silver, tin, aluminum-copper, gold, titanium, titanium-tungsten, tantalum, tantalum-nitrogen, chromium, nickel, or combinations thereof.

A twenty-fifth aspect A25 includes the microelectronic article of any one of the twenty-third through twenty-fourth aspects A23-A24, wherein the dielectric material comprises polyimide, polybenzoxazoles, polyolefin, polystyrene, epoxy resins, parylene, benzocyclobutene, ring-opened norbornen type polymers, or combinations thereof.

A twenty-sixth aspect A26 includes the microelectronic article of any one of the twenty-third through twenty-fifth aspects A23-A25, wherein the at least one redistribution layer comprises greater than or equal to 2 layers and less than or equal to 10 layers of the metal material.

A twenty-seventh aspect A27 includes the microelectronic article of any one of the sixteenth through twenty-sixth aspects A16-A26, wherein the metallized through glass via comprises a diameter greater than or equal to 5 µm and less than or equal to 200 µm.

A twenty-eighth aspect A28 includes the microelectronic article of any one of the sixteenth through twenty-seventh aspects A16-A27, wherein the glass-based substrate comprises a thickness greater than or equal to 0.1 millimeters and less than or equal to 3 millimeters.

A twenty-ninth aspect A29 includes the microelectronic article of any one of the sixteenth through twenty-eighth aspects A16-A28, wherein the compressive layer at the edge of the glass-based substrate comprises a depth of layer at least 5 µm less than a depth of layer of the compressive layer at the first surface of the glass-based substrate, the second surface of the glass-based substrate, and the sidewall of the at least one through glass via.

According to a thirtieth aspect A30, a method of making a microelectronic article comprises: forming at least one through glass via in a glass-based substrate; laser perforating nanoperforations in the glass-based substrate, wherein the nanoperforations define a contour of a die circumscribing the at least one through glass via; strengthening the glass-based substrate; metallizing the at least one through glass via; disposing at least one redistribution layer on the glass-based substrate; and singulating the die from the glass-based substrate to form the microelectronic article.

A thirty-first aspect A31 includes the method of the thirtieth aspect A30, wherein forming the at least one through glass via comprises: forming a through glass via pattern in the glass-based substrate; and etching the through glass via pattern to form the at least one through glass via.

A thirty-second aspect A32 includes the method of either one of the thirtieth or thirty-first aspects A30-A31, wherein the laser perforating the nanoperforations comprises Bessel beam, Kerr effect filamentation, multi-focus laser modification, ablative holes, drilling, or combinations thereof.

A thirty-third aspect A33 includes the method of any one of the thirtieth through thirty-second aspects A30-A32, wherein the laser perforating the nanoperforations occurs at a cutting speed greater than or equal to 1 m/s.

A thirty-fourth aspect A34 includes the method of any one of the thirtieth through thirty-third aspects A30-A33, wherein the contour of the die comprises a rectangle with rounded corners, each of the corners comprising a radius of curvature greater than or equal to 25 µm.

A thirty-fifth aspect A35 includes the method of any one of the thirtieth through thirty-fourth aspects A30-A34, further comprising removing a portion of the at least one redistribution layer that is disposed on the nanoperforations.

A thirty-sixth aspect A36 includes the method of any one of the thirtieth through thirty-fifth aspects A30-A35, further comprising disposing a masking material at least one of on or in the nanoperforations.

A thirty-seventh aspect A37 includes the method of the thirty-sixth aspect A36, wherein the masking material comprises a polymer or tape.

A thirty-eighth aspect A38 includes the method of any one of the thirty-sixth or thirty-seventh aspects A36-A37, further comprising removing the masking material after disposing the at least one redistribution layer on the glass-based substrate.

A thirty-ninth aspect A39 includes the method of any one of the thirtieth through thirty-eighth aspects A30-A38, wherein the laser perforating the nanoperforations occurs prior to forming the at least one through glass via.

A fortieth aspect A40 includes the method of any one of the thirtieth through thirty-ninth aspects A30-A39, wherein the glass-based substrate is strengthened by an ion exchange process, a steam treatment, or a thermal treatment.

A forty-first aspect A41 includes the method of any one of the thirtieth through fortieth aspects A30-A40, further comprising polishing an edge of the microelectronic article.

A forty-second aspect A42 includes the method of any one of the thirtieth through forty-first aspects A30-A41, wherein each of the nanoperforations comprises a diameter greater than or equal to 0.5 µm and less than or equal to 5 µm.

A forty-third aspect A43 includes the method of any one of the thirtieth through forty-second aspects A30-A42, wherein the at least one through glass via comprises a diameter greater than or equal to 5 µm and less than or equal to 200 µm.

A forty-fourth aspect A44 includes the method of any one of the thirtieth through forty-third aspects A30-A43, wherein the glass-based substrate comprises a thickness greater than or equal to 0.1 millimeters and less than or equal to 3 millimeters.

A forty-fifth aspect A45 includes the method of any one of the thirtieth through forty-fourth aspects A30-A44, wherein the at least one redistribution layer comprises a metal material and a dielectric material.

A forty-sixth aspect A46 includes the method of the forty-fifth aspect A45, wherein the metal material comprises copper, aluminum, silver, tin, aluminum-copper, gold, titanium, titanium-tungsten, tantalum, tantalum-nitrogen, chromium, nickel, or combinations thereof.

A forty-seventh aspect A47 includes the method of any one of the forty-fifth or forty-sixth aspects A45-A46, wherein the dielectric material comprises polyimide, polybenzoxazoles, polyolefin, polystyrene, epoxy resins, parylene, benzocyclobutene, ring-opened norbornen type polymers, or combinations thereof.

Additional features and advantages of the glass-based substrates, microelectronic articles including the same, and methods of making the same described herein will be set forth in the detailed description which follows, and in part will be readily apparent to those skilled in the art from that description or recognized by practicing the embodiments described herein, including the detailed description which follows, the claims, as well as the appended drawings.

It is to be understood that both the foregoing general description and the following detailed description describe various embodiments and are intended to provide an overview or framework for understanding the nature and character of the claimed subject matter. The accompanying drawings are included to provide a further understanding of the various embodiments, and are incorporated into and constitute a part of this specification. The drawings illustrate the various embodiments described herein, and together with the description serve to explain the principles and operations of the claimed subject matter.

### BRIEF DESCRIPTION OF THE DRAWINGS

FIG. 1A is a schematic top view of a glass-based substrate, according to embodiments described herein;

FIG. 1B is a schematic top view of a die, according to embodiments described herein;

FIG. 1C is a schematic cross-sectional side view of a glass-based substrate, according to embodiments described herein;

FIG. 2A is a schematic cross-sectional side view of a microelectronic article, according to embodiments described herein;

FIG. 2B is a schematic side view of a microelectronic article, according to embodiments described herein; and

FIG. 3 is a flow chart of a method of making a microelectronic article, according to embodiments described herein.

### DETAILED DESCRIPTION

Reference will now be made in detail to various embodiments of glass-based substrates, microelectronic articles, and methods for making microelectronic articles including a strengthened glass-based substrate that minimizes the likelihood of fractures in the glass-based substrate.

According to embodiments, a glass-based substrate includes a first surface and a second surface opposite the first surface, at least one through glass via extending from the first surface to the second surface of the glass-based substrate, and nanoperforations extending from the first surface to the second surface of the glass-based substrate and defining a contour circumscribing the at least one through glass via. The glass-based substrate includes a compressive layer at the first surface of the glass-based substrate, the second surface of the glass-based substrate, a sidewall of the at least one through glass via, and a sidewall of the nanoperforations.

According to embodiments, a microelectronic article includes a glass-based substrate including a first surface and a second surface opposite the first surface, a metallized through glass via extending from the first surface to the second surface of the glass-based substrate, and at least one redistribution layer disposed on the first surface, the second surface, or both. The glass-based substrate includes a compressive layer at the first surface of the glass-based substrate, the second surface of the glass-based substrate, an edge of the glass-based substrate, and a sidewall of the at least one through glass via.

According to embodiments, a method of making a microelectronic article includes forming at least one through glass via in a glass-based substrate, laser perforating nanoperforations in the glass-based substrate, strengthening the glass-based substrate, metallizing the at least one through glass via, disposing at least one redistribution layer on the glass-based substrate, and singulating the die from the glass-based substrate to form the microelectronic article. The nanoperforations define a contour of a die circumscribing the at least one through glass via.

Various embodiments of glass-based substrates, microelectronic articles including same, and methods of making same will be described herein with specific reference to the appended drawings.

Ranges may be expressed herein as from “about” one particular value, and/or to “about” another particular value. When such a range is expressed, another embodiment includes from the one particular value and/or to the other particular value. Similarly, when values are expressed as approximations, by use of the antecedent “about,” it will be understood that the particular value forms another embodiment. It will be further understood that the endpoints of each of the ranges are significant both in relation to the other endpoint, and independently of the other endpoint.

Directional terms as used herein - for example up, down, right, left, front, back, top, bottom - are made only with reference to the figures as drawn and are not intended to imply absolute orientation.

Unless otherwise expressly stated, it is in no way intended that any method set forth herein be construed as requiring that its steps be performed in a specific order, nor that with any apparatus specific orientations be required. Accordingly, where a method claim does not actually recite an order to be followed by its steps, or that any apparatus claim does not actually recite an order or orientation to individual components, or it is not otherwise specifically stated in the claims or description that the steps are to be limited to a specific order, or that a specific order or orientation to components of an apparatus is not recited, it is in no way intended that an order or orientation be inferred, in any respect. This holds for any possible non-express basis for interpretation, including: matters of logic with respect to arrangement of steps, operational flow, order of components, or orientation of components; plain meaning derived from grammatical organization or punctuation, and; the number or type of embodiments described in the specification.

As used herein, the singular forms “a,” “an,” and “the” include plural referents unless the context clearly dictates otherwise. Thus, for example, reference to “a” component includes aspects having two or more such components, unless the context clearly indicates otherwise.

“Glass-based substrate,” as described herein, refers to a substrate that comprises amorphous glass or glass-ceramics. The term “glass-ceramic” may refer to solids prepared by controlled crystallization of a precursor glass and have one or more crystalline phases and a residual amorphous glass phase.

“Dispose,” as described herein, refers to any coating, depositing, and/or forming of a material onto a surface using any known method in the art. The disposed material may constitute a layer, as described herein. The phrase “disposed on” may include the instance of forming or depositing a material onto a surface such that the material is in direct contact with the surface and also may include the instance where the material is formed or deposited on a surface, with one or more intervening materials between the disposed material and the surface. The intervening materials may constitute a layer, as described herein.

A “layer,” as described herein, refers to a sheet of a material that has generally even thickness covering a surface. A “redistribution layer” (RDL) may refer to the layer comprising dielectric and metal materials that make up an integrated circuit of a microelectronic article, as known by those skilled in the art. In some embodiments, a redistribution layer may be “integrated” such that the dielectric material and the metal material present in the redistribution layer are joined in an intertwined manner. In such embodiments, the dielectric material may be etched, lasered, or otherwise modified to create gaps that are filled with metal material, and vice versa. This process, described further herein, may result in an “integrated” redistribution layer.

A “nanoperforation”, as described herein, refers to a crack, fissure, or opening in a glass-based substrate that extends into and/or through the glass-based substrate. The physical structure of the nanoperforations may be referred to as “filaments” by those skilled in the art. The nanoperforations may penetrate the full depth of the glass. It should be understood that while sometimes described as “holes” or “hole-like,” the nanoperforations disclosed herein may generally not be exclusively void spaces, but are rather portions of the glass-based substrate that have been modified by laser processing as described herein.

The term “singulation”, as used herein, refers to the physical removal of one piece of glass from another. The piece of glass may be referred to herein as a “die”. That is, after singulation, there is no frictional engagement or any contact between the pieces (e.g., there is an air gap between the pieces). According to embodiments, dies may be singulated from a glass-based substrate.

The phrase “contour” as used herein, denotes a plurality of nanoperforations of intended separation on the surface of a glass-based substrate along which the glass-based substrate will be singulated into multiple portions (i.e., “dies”) upon performance of appropriate processing conditions. The contour may define a desired perimeter of the die, which may be singulated from the rest of the glass-based substrate. The physical separation of the dies from the glass-based substrate material surrounding them, which occurs when a crack fully propagates around the internal contours, may be accomplished by additional processing, as described herein.

A “four-point bend test”, as used herein, refers to a four-point bend fixture that determines the flexural strength of glass-based substrates, such as glass and glass-ceramics. The four-point bend test is measured in accordance with ASTM C158-02.

As discussed herein, glass-based substrates are widely used in microelectronic articles. Multiple microelectronic articles may be formed on a glass substrate and then singulated into individual dies that may each have TGVs and/or RDLs. When the individual dies are removed from the glass substrate, the dies may have weak glass edges. The TGVs and RDLs may impart stresses on the glass and longitudinal fracturing may occur that originates from the weakened edges. The fractures may be substantially parallel to the plane of the glass substrate. Conventional solutions may include mechanical polishing to strengthen the die edges, but this process may be time consuming and costly to perform on individual dies. Additionally, lateral fracturing may occur during or immediately after removal from the glass substrate. Another conventional solution may include chemical strengthening of the glass-based substrate. However, chemical strengthening cannot occur after the formation of metallized TGVs and RDLs.

Disclosed herein are glass-based substrates and methods of making microelectronic articles that mitigate the aforementioned problems. Specifically, the glass-based substrates disclosed herein comprise a glass-based substrate comprising at least one through glass via and nanoperforations that define contours of dies. The glass-based substrate is strengthened so that the exposed surfaces of the glass-based substrate (i.e., the sidewalls of the through glass vias and nanoperforations) have a compressive layer. This results in a microelectronic article including a glass-based substrate having an edge strength greater than or equal to 200 MPa, as measured according to a four-point bend test.

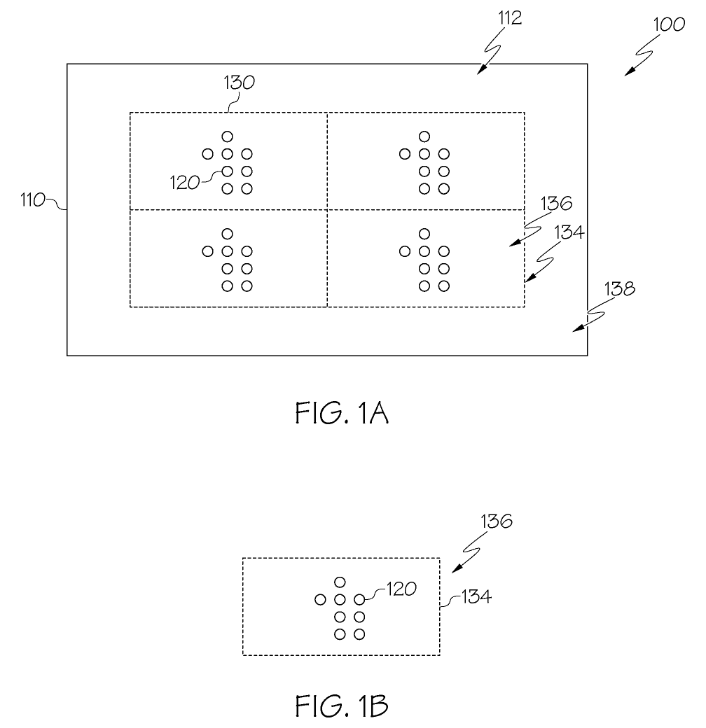

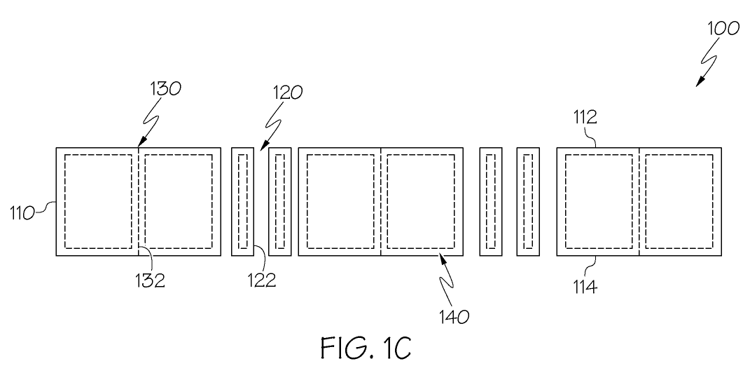

Referring now to FIGS. 1A and 1C, a top view and a cross-sectional side view, respectively, of a glass-based panel 100 according to embodiments herein are depicted. The glass panel 100 may be the glass-based substrate 110 or may comprise the glass-based substrate 110. The glass-based substrate 110 may comprise a first surface 112 and a second surface 114 opposite the first surface 112. The glass-based panel 100 may include at least one through glass via 120 extending from the first surface 112 to the second surface 114 of the glass-based substrate 110. Nanoperforations 130 may extend from the first surface 112 to the second surface 114 of the glass-based substrate 110 and may define a contour 134 circumscribing the at least one through glass via 120. The glass-based substrate 110 may be strengthened. The glass-based substrate 110 may include a compressive layer bat the first surface 112 of the glass-based substrate 110, the second surface 114 of the glass-based substrate 110, a sidewall 122 of the at least one through glass via 120, and a sidewall 132 of the nanoperforations 130.

The glass-based substrate 110 may comprise a first surface 112 and a second surface 114 opposite the first surface 112. The glass-based substrate 110 may comprise at least one through glass via 120. In embodiments, the glass-based substrate 110 may comprise at least two, at least four, at least six, at least eight, at least ten, at least twelve, at least fourteen, at least sixteen, at least eighteen, at least twenty, at least twenty-two, at least twenty-four, at least twenty-six, at least twenty-eight, or at least thirty through glass vias 120. The at least one through glass via 120 may extend through the glass-based substrate 110 from the first surface 112 to the second surface 114. The at least one through glass via 120 may comprise a diameter greater than or equal to 5 µm and less than or equal to 200 µm. In embodiments, the at least one through glass via 120 may comprise a diameter greater than or equal to 5 µm, greater than or equal to 25 µm, greater than or equal to 50 µm, greater than or equal to 75 µm, greater than or equal to 100 µm, greater than or equal to 125 µm, greater than or equal to 150 µm, greater than or equal to 175 µm and less than or equal to 175 µm, less than or equal to 150 µm, less than or equal to 125 µm, less than or equal to 100 µm, less than or equal to 75 µm, less than or equal to 50 µm, less than or equal to 25 µm, or any and all sub-ranges formed from any of these endpoints.

In embodiments, the at least one through glass via 120 may comprise a metal material (not shown in FIGS. 1A or 1C) disposed within. The metal material may comprise copper, aluminum, silver, tin, aluminum-copper, gold, titanium, titanium-tungsten, tantalum, tantalum-nitrogen, chromium, nickel, or combinations thereof.

Still referring to FIGS. 1A and 1C, the glass-based substrate 110 may comprise nanoperforations 130. The nanoperforations 130 may extend from the first surface 112 to the second surface 114 of the glass-based substrate 110. The nanoperforations 130 may define a contour 134 that circumscribes the at least one through glass via 120. In embodiments, each of the nanoperforations 130 may comprise a diameter greater than or equal to 0.5 µm and less than or equal to 5 µm. For example, each of the nanoperforations 130 may comprise a diameter greater than or equal to 1 µm, greater than or equal to 1.5 µm, greater than or equal to 2 µm, greater than or equal to 2.5 µm, greater than or equal to 3 µm, greater than or equal to 3.5 µm, greater than or equal to 4 µm, greater than or equal to 4.5 µm and less than or equal to 4.5 µm, less than or equal to 4 µm, less than or equal to 3.5 µm, less than or equal to 3 µm, less than or equal to 2.5 µm, less than or equal to 2 µm, less than or equal to 1.5 µm, less than or equal to 1 µm, or any and all sub-ranges formed from any of these endpoints. The nanoperforations 130 may form microcracks (not shown) in the glass-based substrate 110. Microcracks extending outward from each nanoperforation 130 may extend 5 µm, 10 µm, 20 µm, or even 50 µm from the nanoperforation 130 itself. The length of the cracks can be controlled during formation of the nanoperforations 130 by adjusting the amount of laser energy deposited to form each nanoperforation 130. These microcracks can extend to the adjacent nanoperforations 130, allowing the contour 134 to become a series of nanoperforations 130 connected together by microcracks.

In embodiments, an interval between adjacent nanoperforations 130 may be greater than or equal to 3 µm and less than or equal to 50 µm. In embodiments, an interval between adjacent nanoperforations 130 may be greater than or equal to 15 µm and less than or equal to 30 µm. For example, an interval between adjacent nanoperforations 130 may be greater than or equal to 5 µm, greater than or equal to 15 µm, greater than or equal to 20 µm, greater than or equal to 25 µm, greater than or equal to 30 µm, greater than or equal to 35 µm, greater than or equal to 40 µm, greater than or equal to 45 µm and less than or equal to 45 µm, less than or equal to 40 µm, less than or equal to 35 µm, less than or equal to 30 µm, less than or equal to 25 µm, less than or equal to 20 µm, less than or equal to 15 µm, less than or equal to 10 µm, less than or equal to 5 µm, or any and all sub-ranges formed from any of these endpoints.

As shown in FIG. 1A, the contour 134 may define a perimeter of at least one die 136. In FIG. 1A, for example, the contour 134 circumscribing the at least one through glass via 120 defines perimeters of four dies 136. FIG. 1B depicts a top view of a single die 136. In embodiments, the contour 134 may define a perimeter of at least two, at least three, at least four, at least five, at least six, at least seven, at least eight, at least nine, at least ten, at least twelve, at least fourteen, at least sixteen, at least eighteen, at least twenty, at least twenty-two, at least twenty-four, at least twenty-six, at least twenty-eight, or at least thirty dies 136. The perimeter of the at least one die 136 may comprise a rectangle with rounded corners, each of the corners comprising a radius of curvature of greater than or equal to 25 µm, such as greater than or equal to 30 µm, greater than or equal to 35 µm, greater than or equal to 40 µm, greater than or equal to 45 µm, greater than or equal to 50 µm, greater than or equal to 55 µm, greater than or equal to 60 µm, greater than or equal to 65 µm, greater than or equal to 70 µm, greater than or equal to 75 µm, greater than or equal to 80 µm, greater than or equal to 85 µm, greater than or equal to 90 µm, greater than or equal to 95 µm, or greater than or equal to 100 µm.

In embodiments, a masking material (not shown in the FIGS.) may be disposed at least one of on or in the nanoperforations 130. The masking material may comprise a polymer or tape. Masking of the nanoperforations 130 may be achieved using a photolithography step, in which a photoresist material (negative or positive) is used to define the region of interest, such as the contours 134 defining the perimeter of dies 136 (FIG. 1A). This is achieved by the deposition of a photoresist across the glass-based substrate 110 by spin coating, lamination, or other photoresist deposition methods. For positive photoresists (where exposure to light weakens the photoresist to create a cavity), a patterned glass mask is open in all regions except the region where the nanoperforations 130 are located. By using an etching step, the photoresist is removed from all areas except where the nanoperforations 130 are located. On the other hand, when negative photoresists are used, only the region of interest is exposed to light. Upon etching, only the nanoperforated protected areas remain. The photoresist may comprise, as non-limiting examples, polymethylmethacrylate (PMMA), cyclized polyisoprene, phenolic Novolak resin, Diazoquinone ester, SU-8 (epoxy-based polymer), or combinations thereof. The individual nanoperforation 130 may be masked (not including the space between adjacent nanoperforations 130) or an array of the nanoperforations 130 (including the space between them) can be covered. Additionally, non-lithography methods can be used for masking of the nanoperforations 130. This can be achieved using cleanroom masking tapes made of polymeric materials such as, but not limited to, polyolefin, polyester, or combinations thereof.

The glass-based substrate 110 may be strengthened by an ion exchange process, a steam treatment, or a thermal treatment. As shown in FIG. 1C, the strengthening process may result in a compressive layer 140 forming at the first surface 112 of the glass-based substrate 110, the second surface 114 of the glass-based substrate 110, a sidewall 122 of the at least one through glass via 120, and a sidewall 132 of the nanoperforations 130. Due to the compressive layer 140, the glass-based substrate 110 may comprise a surface compressive stress greater than or equal to 600 MPa. For example, the glass-based substrate 110 may comprise a surface compressive stress greater than or equal to 625 MPa, greater than or equal to 650 MPa, greater than or equal to 675 MPa, greater than or equal to 700 MPa, greater than or equal to 725 MPa, greater than or equal to 750 MPa, greater than or equal to 775 MPa, greater than or equal to 800 MPa, greater than or equal to 825 MPa, or greater than or equal to 850 MPa.

As used herein, surface compressive stress is measured with a surface stress meter (FSM) such as the FSM-6000, as manufactured by Orihara Industrial Co., Ltd. (Japan). Surface compressive stress measurements rely upon the measurement of the stress optical coefficient (SOC), which is related to the birefringence of the glass article. SOC, in turn, is measured according to Procedure C (Glass Disc Method) described in ASTM standard C770-16, entitled “Standard Test Method for Measurement of Glass Stress-Optical Coefficient,” the contents of which are incorporated herein by reference in their entirety. The values reported for surface compressive stress herein refer to the peak surface compressive stress, unless otherwise indicated. In the embodiments disclosed herein, the surface compressive stress is measured using the FSM for the portions of the glass-based substrate 110 that do not comprise through glass vias 120 and then interpolated, based on these measurements, for the surface compressive stress of the portions of glass-based substrate 110 that do comprise through-glass vias 120.

The compressive layer 140 may comprise a depth of layer within the glass-based substrate 110 that is greater than or equal to 2 µm. In embodiments, the compressive layer 140 may comprise a depth of layer greater than or equal to 4 µm, greater than or equal to 6 µm, greater than or equal to 8 µm, greater than or equal to 10 µm, greater than or equal to 12 µm, greater than or equal to 14 µm, greater than or equal to 16 µm, greater than or equal to 18 µm, greater than or equal to 20 µm, greater than or equal to 22 µm, greater than or equal to 24 µm, greater than or equal to 26 µm, greater than or equal to 28 µm, or greater than or equal to 30 µm, or greater than or equal to 40 µm. As used herein, the depth of layer refers to the depth at which the stress within the glass-based substrate 110 changes from compressive to tensile. Therefore, at the depth of layer, the stress within glass-based substrate 110 crosses from a compressive stress to a tensile stress and thus exhibits a stress value of zero. In embodiments, the compressive layer 140 may comprise a depth of layer as described herein at the sidewall 132 of the nanoperforations 130.

The glass-based substrate 110 may comprise an edge strength greater than or equal to 200 MPa, as measured according to a four-point bend test. The edge strength may be greater than or equal to 220 MPa, greater than or equal to 240 MPa, greater than or equal to 260 MPa, greater than or equal to 280 MPa, greater than or equal to 300 MPa, greater than or equal to 320 MPa, greater than or equal to 340 MPa, greater than or equal to 360 MPa, greater than or equal to 380 MPa, greater than or equal to 400 MPa, greater than or equal to 420 MPa, greater than or equal to 440 MPa, greater than or equal to 460 MPa, greater than or equal to 480 MPa, greater than or equal to 500 MPa, greater than or equal to 520 MPa, greater than or equal to 540 MPa, greater than or equal to 560 MPa, greater than or equal to 580 MPa, greater than or equal to 600 MPa, greater than or equal to 620 MPa, or greater than or equal to 640 MPa, as measured according to a four-point bend test. As described herein, a “four-point bend test” refers to a mechanical test where a glass-based substrate is subjected to bending stress using four loading points in accordance with ASTM C158-02. Without being bound by any particular theory, it is believed that the methods described herein result in a microelectronic article with a through glass via 120 and at least one redistribution layer 150 with a strengthened glass-based substrate 110 that has an edge strength of greater than or equal to 200 MPa.

The glass-based substrate 110 may comprise a thickness greater than or equal to 0.1 millimeters and less than or equal to 3 millimeters. For example, the glass-based substrate 110 may comprise a thickness greater than or equal to 0.5 millimeters, greater than or equal to 1 millimeter, greater than or equal to 1.5 millimeters, greater than or equal to 2 millimeters, greater than or equal to 2.5 millimeters and less than or equal to 2.5 millimeters, less than or equal to 2 millimeters, less than or equal to 1.5 millimeters, less than or equal to 1 millimeter, less than or equal to 0.5 millimeters, or any and all sub-ranges formed from any of these endpoints.

The glass-based substrate 110 may further comprise at least one metal layer and at least one polymer layer (not shown) disposed on the first surface 112 of the glass-based substrate 110, the second surface 114 of the glass-based substrate 110, or both. The metal layer may comprise the metal material, as described herein. The polymer layer may comprise the dielectric material, as described herein.

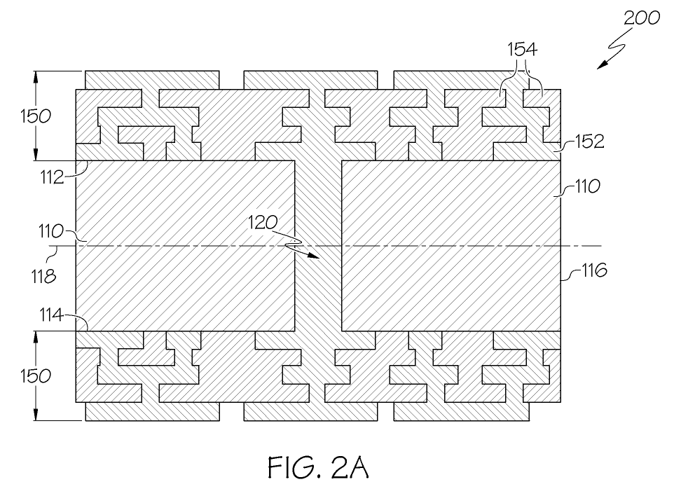

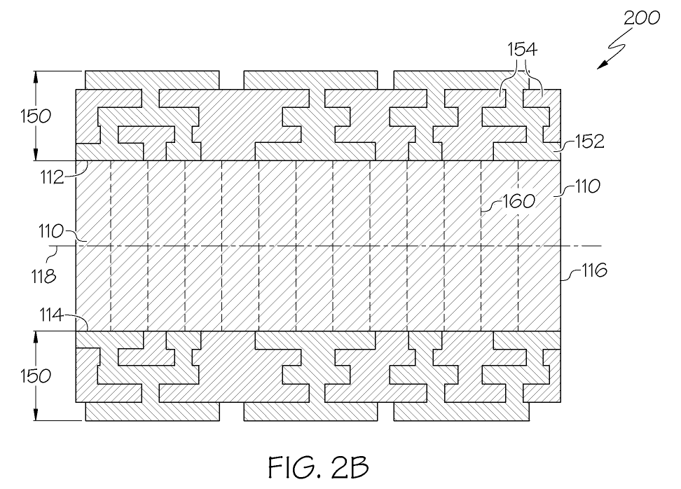

Now referring to FIG. 2A, a cross-sectional side view of a microelectronic article 200 is depicted according to embodiments described herein. The microelectronic article 200 may comprise a glass-based substrate 110 that comprises a first surface 112 and a second surface 114 opposite the first surface 112. A metallized through glass via 120 may extend from the first surface 112 to the second surface 114 of the glass-based substrate 110. At least one redistribution layer 150 may be disposed on the first surface 112, the second surface 114, or both. The glass-based substrate 110 may comprise a compressive layer 140 at the first surface 112 of the glass-based substrate 110, the second surface 114 of the glass-based substrate 110, an edge 116 of the glass-based substrate 110, and a sidewall 122 of the at least one through glass via 120.

In embodiments, the glass-based substrate 110 comprises a die 136. The die 136 may comprise a rectangle with rounded corners, each of the rounded corners comprising a radius of curvature greater than or equal to 25 µm, as described above with respect to the glass-based substrate 110.

Now referring to FIG. 2B, a side view of a microelectronic article 200 is depicted. As shown, the edge 116 of the glass-based substrate 110 may comprise vertical striations 160. These vertical striations 160 may be a result of singulation of the microelectronic article 200 at the nanoperforations 130 of a glass-based substrate 110 as described herein. As a result of singulation, a distance between each of the vertical striations 160 (also known as a “pitch”) may be greater than or equal to 3 µm and less than or equal to 50 µm. In embodiments, a distance between each of the vertical striations 160 may be greater than or equal to 5 µm, greater than or equal to 15 µm, greater than or equal to 20 µm, greater than or equal to 25 µm, greater than or equal to 30 µm, greater than or equal to 35 µm, greater than or equal to 40 µm, greater than or equal to 45 µm and less than or equal to 45 µm, less than or equal to 40 µm, less than or equal to 35 µm, less than or equal to 30 µm, less than or equal to 25 µm, less than or equal to 20 µm, less than or equal to 15 µm, less than or equal to 10 µm, less than or equal to 5 µm, or any and all sub-ranges formed from any of these endpoints. In embodiments, the distance between each of the vertical striations 160 may be less than twice the depth of layer of the glass-based substrate 110.

As discussed above, the contour 134 is formed of a plurality of nanoperforations 130, which may comprise the compressive layer 140 along its sidewalls 132. Furthermore, the glass-based substrate 110 may be cut or singulated along the contour 134 to form a die 136. The cut or singulated edge 116 of the glass-based substrate 110, as cut or singulated along the contour 134, forms the edge 116. Therefore, this cut or singulated edge 116 also comprises the compressive layer 140 as it was formed along the sidewalls 132 of the nanoperforations 130. The compressive layer 140 along the edge 116 of the glass-based substrate 110 extends to a depth of layer, as discussed above.

Referring to FIGS. 2A and 2B, the microelectronic article 200 may comprise at least one redistribution layer 150. In some embodiments, the microelectronic article 200 may comprise a first redistribution layer 150 on the first surface 112 of the glass-based substrate 110 and a second redistribution layer 150 on the second surface 114 of the glass-based substrate 110. In other embodiments, the microelectronic article 200 may comprise either a redistribution layer 150 on the first surface 112 or the second surface 114 of the glass-based substrate 110.

The at least one redistribution layer 150 may comprise a metal material 152 and a dielectric material 154. The metal material 152 and the dielectric material 154 may be disposed on the glass-based substrate 110 in layers. The metal material 152 and the dielectric material 154 may be integrated, such that the two materials are joined in an intertwined manner. The metal material 152 and the dielectric material 154 may be integrated during the formation process of the at least one redistribution layer 150. The metal material 152 may comprise copper, aluminum, silver, tin, aluminum-copper, gold, titanium, titanium-tungsten, tantalum, tantalum-nitrogen, chromium, nickel, or combinations thereof. The dielectric material 154 may comprise polyimide, polybenzoxazoles, polyolefin, polystyrene, epoxy resins, parylene, benzocyclobutene, ring-opened norbornen type polymers, or combinations thereof. In embodiments, the dielectric material may be photo-patternable polyimide.

In embodiments, the at least one redistribution layer 150 may have a thickness of at least 500 nm. For example, the at least one redistribution layer 150 may have a thickness of at least 520 nm, at least 540 nm, at least 560 nm, at least 580 nm, at least 600 nm, at least 560 nm, at least 570 nm, at least 580 nm, at least 590 nm, at least 600 nm.

In embodiments, the at least one redistribution layer 150 may comprise greater than or equal to 2 and less than or equal to 10 layers of the metal material 152. For example, the at least one redistribution layer 150 may comprise greater than or equal to 3, greater than or equal to 4, greater than or equal to 5, greater than or equal to 6, greater than or equal to 7, greater than or equal to 8, greater than or equal to 9 and less than or equal to 9, less than or equal to 8, less than or equal to 7, less than or equal to 6, less than or equal to 5, less than or equal to 4, less than or equal to 3 layers of the metal material 152, or any and all sub-ranges formed from any of these endpoints. In embodiments, the at least one redistribution layer 150 may comprise greater than or equal to 2 and less than or equal to 10 layers of dielectric material 154. For example, the at least one redistribution layer 150 may comprise greater than or equal to 3, greater than or equal to 4, greater than or equal to 5, greater than or equal to 6, greater than or equal to 7, greater than or equal to 8, greater than or equal to 9 and less than or equal to 9, less than or equal to 8, less than or equal to 7, less than or equal to 6, less than or equal to 5, less than or equal to 4, less than or equal to 3 layers of dielectric material 154, or any and all sub-ranges formed from any of these endpoints.

Each of the layers of metal material 152 may comprise a thickness greater than or equal to 0.5 µm and less than or equal to 25 µm. For example, each of the layers of metal material 152 may comprise a thickness greater than or equal to 1 µm, greater than or equal to 2 µm, greater than or equal to 4 µm, greater than or equal to 6 µm, greater than or equal to 8 µm, greater than or equal to 10 µm, greater than or equal to 12 µm, greater than or equal to 14 µm, greater than or equal to 16 µm, greater than or equal to 18 µm, greater than or equal to 20 µm, greater than or equal to 22 µm, greater than or equal to 14 µm and less than or equal to 24 µm, less than or equal to 22 µm, less than or equal to 20 µm, less than or equal to 18 µm, less than or equal to 16 µm, less than or equal to 14 µm, less than or equal to 12 µm, less than or equal to 8 µm, less than or equal to 6 µm, less than or equal to 4 µm, less than or equal to 2 µm, less than or equal to 1 µm, or any and all sub-ranges formed from any of these endpoints.

The microelectronic article 200 may comprise a glass-based substrate 110 that has the same properties as the glass-based substrate 110 described above with respect to FIGS. 1A, 1B, and 1C. The compressive layer 140 and the through glass via 120 may also be the same as described above.

In some embodiments, the edge 116 of the microelectronic article 200 may be polished. The polishing may remove a portion of the edge 116 of the microelectronic article 200. The polishing can reduce the flaw size at the edge 116 of the microelectronic article 200, but if done in a limited fashion, the polishing does not completely remove the compressive layer 140 that provides the compressive stress. Accordingly, it is beneficial to limit the polishing of the microelectronic article 200 so that at least a portion of the compressive layer 140 remains. The net benefit is an increase in the edge strength of the article. As a result, the edge 116 of the glass-based substrate 110 may have a compressive layer 140 with a depth of layer that is at least 5 µm less than the depth of layer of the first surface 112 of the glass-based substrate 110, the second surface 114 of the glass-based substrate 110, and the sidewall 122 of the at least one through glass via 120. For example, the edge 116 of the glass-based substrate 110 may have a depth of layer that is at least 5 µm, at least 6 µm, at least 7 µm, at least 8 µm, at least 9 µm, at least 10 µm, at least 11 µm, at least 12 µm, at least 13 µm, at least 14 µm, or at least 15 µm less than the depth of layer of the first surface 112 of the glass-based substrate 110, the second surface 114 of the glass-based substrate 110, and/or the sidewall 122 of the at least one through glass via 120.

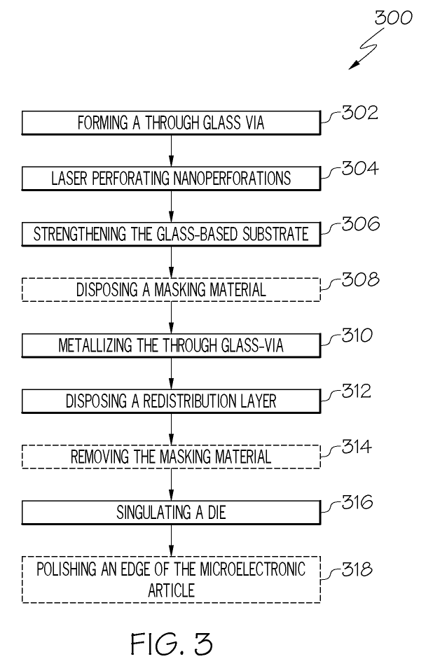

Now referring to FIG. 3, a method of making a microelectronic article 200 is shown at 300. Optional steps are shown in blocks with dotted lines, including blocks 308, 314, and 318. The method 300 may begin at block 302 with forming at least one through glass via 120 in a glass-based substrate 110.

Referring to block 302, at least one through glass via 120 may be formed in the glass-based substrate 110. Referring to FIG. 2A, the at least one through glass via 120 may be formed by chemical etching or laser damaging the glass-based substrate 110. Forming the through glass via 120 may be from any method known in the art, such as, but not limited to, laser methods including Bessel beam, Kerr effect filamentation, ablation, and drilling. In embodiments, forming the at least one through glass via 120 may comprise forming a through glass via pattern in the glass-based substrate 110 and etching the through glass via pattern to form the at least one through glass via 120. The through glass via pattern may be lasered into the glass-based substrate 110. A subsequent etching step may form or further expand the diameter of the through glass vias 120. In such embodiments, etching may comprise exposure to an acid (e.g., HF) or a base (e.g., NaOH or KOH) via immersion, vapor, spray etching, or combinations thereof. An example of formation of the at least one through glass via 120 is described in U.S. Patent No. 9,517,963 B2, which is incorporated by reference herein by its entirety.

Referring back to FIG. 3, the method 300 may continue at block 304 with laser perforating nanoperforations 130 (FIGS. 1A, 1B, and 1C) in the glass-based substrate 110, wherein the nanoperforations 130 define a contour 134 of a die 136 circumscribing the at least one through glass via 120. The laser perforation may be by Bessel beam, Kerr effect filamentation, multi-focus laser modification, ablative holes, drilling, or combinations thereof. Multi-focus laser modification is described in “ Protecting the edge: Ultrafast laser modified C-shape glass edges”, J. Laser Appl. 34, 012014 (2022), which is incorporated by reference herein by its entirety. An example of a process of laser perforating nanoperforations 130 is described in EP Patent No. 3311947 B1, which is incorporated by reference herein by its entirety. Laser perforating the nanoperforations 130 may occur at a cutting speed greater than or equal to 1 m/s, such as greater than or equal to 1.5 m/s, greater than or equal to 2 m/s, greater than or equal to 2.5 m/s, greater than or equal to 3 m/s, greater than or equal to 3.5 m/s, greater than or equal to 4 m/s, greater than or equal to 4.5 m/s, or greater than or equal to 5 m/s. Laser perforating the nanoperforations 130 may occur prior to or after forming the at least one through glass via 120. The nanoperforations 130 may define a contour 134 of a die 136, or multiple contours 134, circumscribing the at least one through glass via 120, as described previously herein. The laser processing may form a line of nanoperforations 130 that are connected. The lasering process may leave a frame 138 of the glass-based substrate 110 attached such that the nanoperforations 130 do not extend to an edge 116 of the glass-based substrate 110, as shown in FIG. 1A. Thus, even if a crack propagates between each nanoperforation 130, no crack will extend to the glass-based substrate 110 edge 116. Additionally, the lasering process may be a zero kerf process. As used herein, “zero kerf, or "no kerf" cut, is an open cut geometry that is the same width as the laser's cut path. “Kerf” refers to the width of material that is removed during the cutting process. As such, the lasered parts may remain frictionally engaged such that the dies 136 do not fall out of the glass-based substrate 110 when undergoing subsequent processing, such as formation of redistribution layers 150.

Referring again to FIG. 3, the method 300 may continue at block 306 with strengthening the glass-based substrate 110. Strengthening the glass-based substrate 110 may be by an ion exchange process, a steam treatment, or a thermal treatment. Strengthening of the glass-based substrate 110 may form the compressive layer 140. The compressive layer 140 may have a depth of layer within the glass-based substrate 110 and the glass-based substrate 110 may have a surface compressive strength as described herein. Without being bound by any particular theory, strengthening the glass-based substrate 110 after formation of the at least one through glass via 120 and the nanoperforations 130 may result in a microelectronic article 200 (FIG. 2) that has strengthened outer edges 116 – where the outer edges 116 are formed by separating the dies 136 from the glass-based substrate 110 at the nanoperforations 130 – and strengthened sidewalls 122 of the through glass vias 120. The resulting microelectronic article 200 may be less prone to longitudinal fractures along the plane (i.e., substantially parallel to the mid-plane 118) of the glass-based substrate 110. In conventional processes, dies 136 are singulated after strengthening, which results in dies 136 with no compressive layer 140 at the edges 116 of the microelectronic article 200. These edges 116 may be four to five times weaker than the edge strength of microelectronic articles 200 with strengthened edges 116, as described herein.

As stated, the glass-based substrate 110 may be strengthened via an ion exchange process to produce the compressive layer 140. In the ion exchange process, ions at or near an outer surface of the glass-based substrate 110, such as at the first surface 112 and the second surface 114, may be replaced by – or exchanged with – larger ions from a salt bath having the same valence or oxidation state (hereinafter referred to as the “larger ion” or “exchanged ion”). As described herein, the ions from the salt bath may also diffuse into defects in the glass-based substrate 110, such as the through glass via 120 and the nanoperforations 130. As such, a sidewall 122 of the at least one through glass via 120 and a sidewall 132 of the nanoperforations 130 may be strengthened to form the compressive layer 140. At this point, the dies 136 defined by contours 134 may still be attached to the glass-based substrate 110. The entire length of the lasered contour 134 defined by the nanoperforations 130 may be strengthened, including each of the nanoperforations 130 and the intervals between the nanoperforations 130.

Ion exchange processes are typically carried out by immersing a glass article in a molten salt bath (or two or more molten salt baths) containing the larger ions to be exchanged with the smaller ions in the glass article. It should be noted that aqueous salt baths may also be utilized. In addition, the composition of the bath(s) may comprise more than one type of larger ion (e.g., Na+ and K+) or a single larger ion. It will be appreciated by those skilled in the art that parameters for the ion exchange process, comprising, but not limited to, bath composition and temperature, immersion time, the number of immersions of the glass article in a salt bath (or baths), use of multiple salt baths, additional steps such as annealing, washing, and the like, may generally be determined by the composition of the glass-based substrate 110 and the desired depth of layer and surface compressive strength of the glass-based substrate 110 that results from strengthening. Exemplary molten bath compositions may comprise nitrates, sulfates, and chlorides of the larger alkali metal ion. Typical nitrates may comprise, but are not limited to, KNO₃, NaNO₃, LiNO₃, NaSO₄ and combinations thereof. The temperature of the molten salt bath typically may be in a range from about 380 ºC up to about 500 ºC, while immersion times may range from about 15 minutes up to about 100 hours depending on the glass thickness, bath temperature and glass (or monovalent ion) diffusivity. However, temperatures and immersion times different from those described above may also be used.

In embodiments, the glass-based substrate 110 may be immersed in a molten salt bath of 100% NaNO₃, 100% KNO₃, or a combination of NaNO₃ and KNO₃ having a temperature from about 370 °C to about 500 °C. In some embodiments, the glass-based substrate 110 may be immersed in a molten mixed salt bath comprising from about 5% to about 90% KNO₃ and from about 10% to about 95% NaNO₃. In one or more embodiments, the glass-based substrate 110 may be immersed in a second bath, after immersion in a first bath. The first and second baths may have different compositions and/or temperatures from one another. The immersion times in the first and second baths may vary. For example, immersion in the first bath may be longer than the immersion in the second bath. In embodiments, the glass-based substrate 110 may be immersed in a molten, mixed salt bath comprising NaNO₃ and KNO₃ (e.g., 49%/51%, 50%/50%, 51%/49%) having a temperature less than about 420 °C (e.g., about 400 °C or about 380 °C). for less than about 5 hours, or even about 4 hours or less.

In other embodiments, the glass-based substrate 110 may be strengthened via a steam treatment to produce the compressive layer 140. Steam treatment may generally refer to a process by which the glass-based substrate 110 is exposed to water under any appropriate conditions. The exposure may be carried out in any appropriate device, such as a furnace with relatively humidity control. During steam treatment, water may diffuse into the glass-based substrate 110 which forms the compressive layer 140. Examples of steam treatments that may be used to strengthen the glass-based substrate 110 described herein are disclosed in at least U.S. Patent Application 11,339,084 and U.S. Patent Application 11,370,696, the teachings of each of which are incorporated by reference in their entirety herein. The technical aspects of these disclosures may further describe the methods described herein with respect to FIG. 3.

In embodiments, steam treatment may include exposing the glass-based substrate 110 to an environment comprising a nominal relative humidity greater than or equal to 5%. In embodiments, the glass-based substrate 110 may be exposed to an environment comprising a nominal relative humidity greater than or equal to 5%, greater than or equal to 10%, greater than or equal to 20%, greater than or equal to 30%, greater than or equal to 40%, greater than or equal to 50%, greater than or equal to 60%, greater than or equal to 70%, greater than or equal to 80%, or even greater than or equal to 90%. In embodiments, the glass-based substrate 110 may be exposed to an environment comprising a nominal relative humidity less than or equal to 100%, less than or equal to 90%, less than or equal to 80%, less than or equal to 70%, less than or equal to 60%, less than or equal to 50%, less than or equal to 40%, less than or equal to 30%, less than or equal to 20%, or even less than or equal to 10%. In embodiments, the glass-based substrate 110 may be exposed to an environment comprising a nominal relative humidity greater than or equal to 5% and less than or equal to 100%, greater than or equal to 5% and less than or equal to 90%, greater than or equal to 5% and less than or equal to 80%, greater than or equal to 5% and less than or equal to 70%, greater than or equal to 5% and less than or equal to 60%, greater than or equal to 5% and less than or equal to 50%, greater than or equal to 5% and less than or equal to 40%, greater than or equal to 5% and less than or equal to 30%, greater than or equal to 5% and less than or equal to 20%, greater than or equal to 5% and less than or equal to 10%, greater than or equal to 10% and less than or equal to 100%, greater than or equal to 10% and less than or equal to 90%, greater than or equal to 10% and less than or equal to 80%, greater than or equal to 10% and less than or equal to 70%, greater than or equal to 10% and less than or equal to 60%, greater than or equal to 10% and less than or equal to 50%, greater than or equal to 10% and less than or equal to 40%, greater than or equal to 10% and less than or equal to 30%, greater than or equal to 10% and less than or equal to 20%, greater than or equal to 20% and less than or equal to 100%, greater than or equal to 20% and less than or equal to 90%, greater than or equal to 20% and less than or equal to 80%, greater than or equal to 20% and less than or equal to 70%, greater than or equal to 20% and less than or equal to 60%, greater than or equal to 20% and less than or equal to 50%, greater than or equal to 20% and less than or equal to 40%, greater than or equal to 20% and less than or equal to 30%, greater than or equal to 30% and less than or equal to 100%, greater than or equal to 30% and less than or equal to 90%, greater than or equal to 30% and less than or equal to 80%, greater than or equal to 30% and less than or equal to 70%, greater than or equal to 30% and less than or equal to 60%, greater than or equal to 30% and less than or equal to 50%, greater than or equal to 30% and less than or equal to 40%, greater than or equal to 40% and less than or equal to 100%, greater than or equal to 10% and less than or equal to 90%, greater than or equal to 40% and less than or equal to 80%, greater than or equal to 40% and less than or equal to 70%, greater than or equal to 40% and less than or equal to 60%, greater than or equal to 40% and less than or equal to 50%, greater than or equal to 50% and less than or equal to 100%, greater than or equal to 50% and less than or equal to 90%, greater than or equal to 50% and less than or equal to 80%, greater than or equal to 50% and less than or equal to 70%, greater than or equal to 50% and less than or equal to 60%, greater than or equal to 60% and less than or equal to 100%, greater than or equal to 60% and less than or equal to 90%, greater than or equal to 60% and less than or equal to 80%, greater than or equal to 60% and less than or equal to 70%, greater than or equal to 70% and less than or equal to 100%, greater than or equal to 70% and less than or equal to 90%, greater than or equal to 70% and less than or equal to 80%, greater than or equal to 80% and less than or equal to 100%, greater than or equal to 80% and less than or equal to 90%, or even greater than or equal to 90% and less than or equal to 100%, or any and all sub-ranges formed from any of these endpoints.

In embodiments, during the steam treatment, the glass-based substrate 110 may be exposed to an environment comprising a pressure greater than or equal to 0.029 MPa and less than or equal to 8.592 MPa. In embodiments, during the steam treatment, the glass-based substrate 110 may be exposed to an environment comprising a pressure greater than or equal to 0.029 MPa, greater than or equal to 0.050 MPa, greater than or equal to 0.100 MPa, greater than or equal to 0.500 MPa, or even greater than or equal to 1.000 MPa. In embodiments, the glass-based substrate 110 may be exposed to an environment comprising a pressure less than or equal to 8.592 MPa, less than or equal to 6.000 MPa, less than or equal to 4.000 MPa, or even less than or equal to 2.000 MPa. In embodiments, the glass-based substrate 110 may be exposed to an environment comprising a pressure greater than or equal to 0.029 MPa and less than or equal to 8.592 MPa, greater than or equal to 0.029 MPa and less than or equal to 6.000 MPa, greater than or equal to 0.029 MPa and less than or equal to 4.000 MPa, greater than or equal to 0.029 MPa and less than or equal to 2.000 MPa, greater than or equal to 0.050 MPa and less than or equal to 8.592 MPa, greater than or equal to 0.050 MPa and less than or equal to 6.000 MPa, greater than or equal to 0.050 MPa and less than or equal to 4.000 MPa, greater than or equal to 0.050 MPa and less than or equal to 2.000 MPa, greater than or equal to 0.100 MPa and less than or equal to 8.592 MPa, greater than or equal to 0.100 MPa and less than or equal to 6.000 MPa, greater than or equal to 0.100 MPa and less than or equal to 4.000 MPa, greater than or equal to 0.100 MPa and less than or equal to 2.000 MPa, greater than or equal to 0.500 MPa and less than or equal to 8.592 MPa, greater than or equal to 0.500 MPa and less than or equal to 6.000 MPa, greater than or equal to 0.500 MPa and less than or equal to 4.000 MPa, greater than or equal to 0.500 MPa and less than or equal to 2.000 MPa, greater than or equal to 1.000 MPa and less than or equal to 8.592 MPa, greater than or equal to 1.000 MPa and less than or equal to 6.000 MPa, greater than or equal to 1.000 MPa and less than or equal to 4.000 MPa, or even greater than or equal to 1.000 MPa and less than or equal to 2.000 MPa, or any and all sub-ranges formed from any of these endpoints.

In embodiments, during the steam treatment, the glass-based substrate 110 may be exposed to an environment comprising a temperature greater than or equal to 75 °C and less than or equal to 350 °C. In embodiments, during the steam treatment, the glass-based substrate 110 may be exposed to an environment comprising a temperature greater than or equal to 75 °C, greater than or equal to 85 °C, greater than or equal to 100 °C, greater than or equal to 150 °C, or even greater than or equal to 200 °C. In embodiments, the glass-based substrate 110 may be exposed to an environment comprising a temperature less than or equal to 350 °C, less than or equal to 300 °C, less than or equal to 250 °C, or even less than or equal to 200 °C. In embodiments, the glass-based substrate 110 may be exposed to an environment comprising a temperature greater than or equal to 75 °C and less than or equal to 350 °C, greater than or equal to 75 °C and less than or equal to 300 °C, greater than or equal to 75 °C and less than or equal to 250 °C, greater than or equal to 75 °C and less than or equal to 200 °C, greater than or equal to 85 °C and less than or equal to 350 °C, greater than or equal to 85 °C and less than or equal to 300 °C, greater than or equal to 85 °C and less than or equal to 250 °C, greater than or equal to 85 °C and less than or equal to 200 °C, greater than or equal to 100 °C and less than or equal to 350 °C, greater than or equal to 100 °C and less than or equal to 300 °C, greater than or equal to 100 °C and less than or equal to 250 °C, greater than or equal to 100 °C and less than or equal to 200 °C, greater than or equal to 150 °C and less than or equal to 350 °C, greater than or equal to 150 °C and less than or equal to 300 °C, greater than or equal to 150 °C and less than or equal to 250 °C, greater than or equal to 150 °C and less than or equal to 200 °C, greater than or equal to 200 °C and less than or equal to 350 °C, greater than or equal to 200 °C and less than or equal to 300 °C, or even greater than or equal to 200 °C and less than or equal to 250 °C, or any and all sub-ranges formed from any of these endpoints.

In embodiments, during the steam treatment, the glass-based substrate 110 may be exposed to the water vapor containing environment for a time period sufficient to produce the desired degree of hydrogen-containing species diffusion and the desired depth of layer. In embodiments, during the steam treatment, the glass-based substrate 110 may be exposed to the water vapor containing environment for greater than or equal to 1 day, such as greater than or equal to 2 days, greater than or equal to 3 days, greater than or equal to 4 days, greater than or equal to 5 days, greater than or equal to 6 days, greater than or equal to 7 days, greater than or equal to 8 days, greater than or equal to 9 days, greater than or equal to 10 days, greater than or equal to 15 days, greater than or equal to 20 days, greater than or equal to 25 days, greater than or equal to 30 days, greater than or equal to 35 days, greater than or equal to 40 days, greater than or equal to 45 days, greater than or equal to 50 days, greater than or equal to 55 days, greater than or equal to 60 days, greater than or equal to 65 days, or more. In embodiments, the glass-based substrate 110 may be exposed to the water vapor containing environment for a time period from greater than or equal to 1 day to less than or equal to 70 days, such as greater than or equal to 2 days to less than or equal to 65 days, greater than or equal to 3 days to less than or equal to 60 days, greater than or equal to 4 days to less than or equal to 55 days, greater than or equal to 5 days to less than or equal to 45 days, greater than or equal to 6 days to less than or equal to 40 days, greater than or equal to 7 days to less than or equal to 35 days, greater than or equal to 8 days to less than or equal to 30 days, greater than or equal to 9 days to less than or equal to 25 days, greater than or equal to 10 days to less than or equal to 20 days, 15 days, or any sub-ranges formed from any of these endpoints. The exposure conditions may be modified to reduce the time necessary to produce the desired amount of hydrogen-containing species diffusion into the glass-based substrate 110. For example, the temperature and/or relative humidity may be increased to reduce the time required to achieve the desired degree of hydrogen-containing species diffusion and depth of layer into the glass-based substrate 110.

Referring still to method 300 and block 306, in other embodiments, the glass-based substrate 110 may be strengthened via a thermal treatment to produce the compressive layer 140. Thermal treatment may comprise heating the glass-based substrate 110 at certain temperatures and durations and then rapidly cooling to form the compressive layer 140. For example, the glass-based substrate 110 may be exposed to an environment comprising a temperature greater than or equal to 550 °C and less than or equal to 800 °C for a duration of greater than 2 hours and less than 20 hours. The glass-based substrate 110 may then be rapidly cooled using forced air drafts (also known as “quenching”) to form the compressive layer 140. Examples of thermal treatments that may be used to strengthen the glass-based substrate 110 described herein are disclosed in “Chapter 5: Thermal Tempering of Glass” R. Gardon, Glass Science and Technology, Vol. 5, 1980, p. 145-216, “Glass: Annealing and Tempering”, M. Hubert and P. Lezzi, Encyclopedia of Materials: Technical Ceramics and Glasses, Vol. 2, 2021, p. 623-631, and “Effect of physical tempering on the mechanical properties of aluminosilicate glass” Yang et. al, Journal of Non-Crystalline Solids, 619 (2023) 122574, the teachings of each of which are incorporated by reference in their entirety herein. The technical aspects of these disclosures may further describe the methods described herein with respect to FIG. 3.

Referring again to FIG. 3, the method 300 may continue at block 310, with metallizing the through glass via 120. In some embodiments, the through glass via 120 may comprise the metal material 152 disposed within. As used herein, a “metallized through glass via” may refer to a through glass via that comprises the metal material 152. The metal material 152 may be introduced into the through glass via 120. In embodiments, the metal material 152 may completely fill the through glass via 120. In one or more embodiments, the metal material 152 may coat the surfaces of the through glass via 120. The metallized through glass via 120 may serve as an electric connection through the microelectronic article 200.

Referring still to FIG. 3, the method 300 may continue at block 312, with disposing at least one redistribution layer 150 on the glass-based substrate 110. As shown in FIGS. 2A and 2B, two redistribution layers 150 may be disposed on the glass-based substrate 110. The redistribution layer 150 may be formed (i.e., disposed on the glass-based substrate 110) by at least one cycle of disposing the metal material 152 on the glass-based substrate 110 and disposing the dielectric material 154 at least one of on or between the metal material 152. Depositing the redistribution layer 150 on the glass-based substrate 110 may comprise multiple of these cycles. For example, depositing the at least one redistribution layer 150 on the glass-based substrate 110 may comprise at least two, at least three, at least four, at least five, at least six, at least seven, at least eight, at least nine, or at least ten cycles.

Referring to FIGS. 2A and 2B, during each of these cycles, the metal material 152 may be chemically etched or patterned, resulting in gaps with no metal material 152 present. The dielectric material 154 may be disposed on the patterned metal material 152 such that the dielectric material 154 fills the gaps in the metal material 152 while simultaneously forming on top of the patterned metal material 152. The same process may be employed on the dielectric material 154 of chemical etching or patterning to create gaps in the dielectric material 154 and disposing metal material 152 to fill the gaps in the dielectric material 154 with the formation of metal material 152 disposed on the newly formed dielectric material 154. The cycle may be subsequently repeated with the metal material 152 and the dielectric material 154 to build up the desired thickness and makeup of the redistribution layer 150. This process may create the “integrated” redistribution layer 150 wherein the metal material 152 and the dielectric material 154 are joined in an intertwined, or interlocked, manner. Additionally, in some embodiments, the redistribution layers 150 may be symmetric to each other as reflected across the mid-plane 118 of the glass-based substrate 110, wherein each redistribution layer 150 may comprise the metal material 152 and the dielectric material 154 in the same disposal order and/or same etched pattern reflected across the mid-plane 118. In other embodiments (not shown), the redistribution layers 150 may not be symmetric with respect to the mid-plane 118.

In some embodiments, one redistribution layer 150 may be deposited on either the first surface 112 or the second surface 114 of the glass-based substrate 110. In other embodiments, the at least one redistribution layer 150 may be deposited on each of the first surface 112 and the second surface 114 as shown in FIG. 2A and 2B. In such embodiments, the at least one redistribution layer 150 may comprise a first redistribution layer disposed on the first surface 112 of the glass-based substrate 110 and a second redistribution layer disposed on the second surface 114 of the glass-based substrate 110. The first redistribution layer 150 may be the same as or different from the second redistribution layer 150. As a non-limiting example, the first redistribution layer 150 may have a different disposal sequence of metal material 152 and dielectric material 154 than the second redistribution layer 150. In other embodiments, the first redistribution layer 150 may have a different chemical etching or patterning of the metal material 152 and/or the dielectric material 154 than the second redistribution layer 150.

Referring back to FIG. 3, the method 300 may continue at optional block 308 with disposing a masking material (not shown in FIGS. 2A and 2B) at least one of on or in the nanoperforations 130. The masking material may be disposed after strengthening of the glass-based substrate 110. The masking material may comprise a polymer, such as a removable polymer resistant to heat, or may comprise tape. The masking material may prevent possible entrapment of liquids, which could contaminant or block the nanoperforations 130. Masking may also prevent the “popcorn effect”, which is a phenomenon that may occur during subsequent downstream processing of the microelectronic article 200. The popcorn effect occurs due to evaporation of trapped liquids during high temperature processes, including disposal of redistribution layers 150 and/or any annealing steps that may be performed. Referring still to FIG. 3 at optional block 314, the masking material may be removed after disposing the at least one redistribution layer 150 on the glass-based substrate 110 (FIG. 2). In such embodiments, the redistribution layer 150 may not be present on the nanoperforations 130. In embodiments where no masking material is used, a portion of the at least one redistribution layer 150 may be disposed on the nanoperforations 130 and may prevent the individual dies 136 from separating from each other. In such embodiments, the portion of the redistribution layer 150 that is disposed on the nanoperforations 130 may be removed prior to singulation. Removal may be by any method known in the art, such as, but not limited to, wet or dry etching, CO₂ laser or UV femtosecond pulsed laser.

Referring still to FIG. 3, the method 300 may continue at block 316 with singulating the die 136 from the glass-based substrate 110 to form the microelectronic article 200. The die 136 may be singulated by separating the die 136 from the glass-based substrate 110 at the contours 134 formed by the nanoperforations 130 (FIGS. 1A and 1B). Singulation may occur, for example, by making cuts in the frame section 138 of the glass-based substrate 110, using a nano-perforation laser. In embodiments, the stress inside the glass-based substrate 110 itself, which is imparted by the ion exchange process, may be sufficient to propagate cracks along the nanoperforations 130 causing the dies 136 to separate, resulting in singulated microelectronic articles 200. Alternatively, a mechanical cutting method may be used to make the cuts in the frame section 138 of the glass-based substrate 110. If after such frame section 138 is cut, the dies 136 remain attached to the glass-based substrate 110, which may occur if coatings cover or penetrate the contours 134, then it is possible to apply stress along the nanoperforations 130 such that the dies 136 are released from the glass-based substrate 110. Such a stress may be applied, for example, by directing an infrared laser beam along or near the nanoperforations 130, applying a mechanical force to the nanoperforations 130, or other suitable method. As the sidewalls 132 of the nanoperforations 130 were subjected to strengthening, the singulated microelectronic articles 200 (FIG. 2) may have strengthened edges 116, including the compressive layer 140 (FIG. 1C). This is in contrast with other alternative processes involving the cutting of individual parts and grinding to remove much more (e.g., more than 100 µm) material to due to cutting damage, and then polishing. The method 300 (FIG. 3) beneficially eliminates the time and cost of the individual part edge finishing step.

Referring to FIG. 3, the method may continue at optional block 318 with polishing an edge 116 of the microelectronic article 200. After singulation, the edge 116 of the microelectronic article 200 may not be uniform, such that it has jagged or chipped edges 116 where the nanoperforations 130 were lasered (FIG. 1A). Thus, the edge 116 of the microelectronic article 200 (FIG. 2) may be polished to reduce the flaw size of the edge 116, improving the overall edge strength even further, and also to allow for uniformity and smoothness of the microelectronic article 200 edges 116. As described herein, a benefit of the process described herein is that an amount of polishing required to provide relatively high edge strength (i.e., greater than or equal to 200 MPa, as measured according to a four-point bend test) is relatively low. In embodiments, polishing may remove greater than or equal to 5 µm from the edge 116 of the microelectronic article 200. Polishing may remove greater than or equal to 6 µm, greater than or equal to 7 µm, greater than or equal to 8 µm, greater than or equal to 9 µm, greater than or equal to 10 µm from the edge 116 of the microelectronic article 200. In some embodiments, polishing may remove less than or equal to 50 µm, less than or equal to 45 µm, less than or equal to 40 µm, less than or equal to 35 µm, less than or equal to 30 µm, less than or equal to 25 µm, less than or equal to 20 µm from the edge 116 of the microelectronic article 200. In such embodiments, the depth of layer of the compressive layer 140 may be less than the depth of layer of the compressive layer 140 prior to polishing. The polishing may be brush polishing. Polishing may be symmetrical so that the polished edges 116 have a substantially similar shape and a substantially similar amount of material is removed.

It will be apparent to those skilled in the art that various modifications and variations may be made to the embodiments described herein without departing from the spirit and scope of the claimed subject matter. Thus, it is intended that the specification cover the modifications and variations of the various embodiments described herein provided such modification and variations come within the scope of the appended claims and their equivalents.

What is claimed is:

1. A glass-based substrate comprising:
a first surface and a second surface opposite the first surface;
at least one through glass via extending from the first surface to the second surface of the glass-based substrate; and
nanoperforations extending from the first surface to the second surface of the glass-based substrate and defining a contour circumscribing the at least one through glass via,
wherein the glass-based substrate comprises a compressive layer at the first surface of the glass-based substrate, the second surface of the glass-based substrate, a sidewall of the at least one through glass via, and a sidewall of the nanoperforations.

2. The glass-based substrate of claim 1, wherein the contour defines a perimeter of at least one die.

3. The glass-based substrate of claim 1, wherein the glass-based substrate comprises a surface compressive stress greater than or equal to 600 MPa.

4. The glass-based substrate of claim 1, wherein the compressive layer at the sidewall of the nanoperforations comprises a depth of layer greater than or equal to 2 µm.

5. The glass-based substrate of claim 1, wherein the at least one through glass via comprises a metal material disposed therein.

6. The glass-based panel of claim 1, wherein the glass-based substrate is strengthened by an ion exchange process, a steam treatment, or a thermal treatment to form the compressive layer.

7. The glass-based panel of claim 1, further comprising at least one metal layer and at least one polymer layer disposed on the first surface of the glass-based substrate, the second surface of the glass-based substrate, or both.

8. A microelectronic article, the microelectronic article comprising:
a glass-based substrate comprising a first surface and a second surface opposite the first surface;
a metallized through glass via extending from the first surface to the second surface of the glass-based substrate;
at least one redistribution layer disposed on the first surface, the second surface, or both, wherein:
the glass-based substrate comprises a compressive layer at the first surface of the glass-based substrate, the second surface of the glass-based substrate, an edge of the glass-based substrate, and a sidewall of the at least one through glass via.

9. The microelectronic article of claim 8, wherein the glass-based substrate comprises an edge strength greater than or equal to 200 MPa, as measured according to a four-point bend test.

10. The microelectronic article of claim 8, wherein the edge of the glass-based substrate comprises vertical striations and a distance between each of the vertical striations is greater than or equal to 3 µm and less than or equal to 50 µm.

11. The microelectronic article of claim 8, wherein the glass-based substrate comprises a surface compressive stress greater than or equal to 600 MPa.

12. The microelectronic article of claim 8, wherein the glass-based substrate comprises a depth of layer at the edge of the glass-based substrate greater than or equal to 2 µm.

13. The microelectronic article of claim 8, wherein the at least one redistribution layer comprises a metal material and a dielectric material.

14. The microelectronic article of claim 8, wherein the compressive layer at the edge of the glass-based substrate comprises a depth of layer at least 5 µm less than a depth of layer of the compressive layer at the first surface of the glass-based substrate, the second surface of the glass-based substrate, and the sidewall of the at least one through glass via.

15. A method of making a microelectronic article, the method comprising:
forming at least one through glass via in a glass-based substrate;
laser perforating nanoperforations in the glass-based substrate, wherein the nanoperforations define a contour of a die circumscribing the at least one through glass via;
strengthening the glass-based substrate;
metallizing the at least one through glass via;
disposing at least one redistribution layer on the glass-based substrate; and
singulating the die from the glass-based substrate to form the microelectronic article.

16. The method of claim 15, wherein forming the at least one through glass via comprises:
forming a through glass via pattern in the glass-based substrate; and
etching the through glass via pattern to form the at least one through glass via.

17. The method of claim 15, wherein the laser perforating the nanoperforations comprises Bessel beam, Kerr effect filamentation, multi-focus laser modification, ablative holes, drilling, or combinations thereof.

18. The method of claim 15, wherein the laser perforating the nanoperforations occurs prior to forming the at least one through glass via.

19. The method of claim 15, wherein the glass-based substrate is strengthened by an ion exchange process, a steam treatment, or a thermal treatment.

20. The method of claim 15, further comprising polishing an edge of the microelectronic article.
